(19) United States
(12) Patent Application Publication
(10) Pub. No.: US 2008/0303130 A1
(43) Pub. Date: Dec. 11, 2008

(54) Package on package structure

(76) Inventor: Chin-Ti Chen, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/007,064

(22) Filed: Jan. 7, 2008

(30) Foreign Application Priority Data
Jun. 11, 2007 (TW) 96141846

(51) Int. Cl. H01L 23/48; H01L 23/02

(52) U.S. Cl. 257/686; 257/696; 257/E23.019; 257/E23.002

(57) ABSTRACT

A package on package structure includes a first chip package, a second chip package and a conductive film. The first chip package has a portion of first conductive lead which is exposed to the encapsulation body of the first chip package. The conductive film is arranged between the first chip package and the second chip package to adhere to them and electrically connect the first conductive lead and the second chip package. The above-mentioned package on package structure can improve short-circuit phenomenon between leads.

### BACKGROUND OF THE INVENTION

1. Field of the Invention

The present invention relates to a package on package structure, and more particularly relates to the package on package structure having a lead-frame chip package.

2. Description of the Related Art

Currently, most electronic devices toward to the slim, compact, lightweight and multi-function are inevitable tendency. So, the traditional single chip packaging technology can not satisfy with the requirement gradually. In view of the above, the development point of the package techniques is to reduce their packaging size and packaging thickness by using various stacking package techniques to package the different kinds of functional chips.

For example, one of the stacking package techniques is package on package (POP), it may stack two individual chip packages by using process procedure. The two chip packages are packaged and tested respectively and then stacked to adhere with each other, so as to reduce the process risk and elevate the qualified production rate. In the conventional package on package structure, two chip packages may be electrically connected by using solder. However, the stacking process of the lead-frame package encountered with a bottleneck.

Illustratively, when the number of the lead of the lead-frame chip package is increased to cause the space narrowing down between two leads, two lead-frame chip packages electrically connected with each other by using solder may cause the short-circuit, meanwhile, the chip package may be damaged easily and affected its solderability during reforming the lead-frame chip package.

To sum up, how to improve and elevate the qualified production rate for the stacked structure of the lead-frame chip package of is a goal needed to overcome.

### SUMMARY OF THE INVENTION

In order to solve the above-mentioned problems, one object of this invention is to provide a package on package structure, wherein a conductive lead inside lead-frame chip package is used to be as the conductive contact between those stacked chip packages, and a conductive film is applied as the conductive and adhesive material between the stacked chip packages. Thus, a phenomenon of short-circuit can be improved efficiently.

To achieve the foregoing purposes, one embodiment of present invention is to provide a package on package structure including a first chip package, a second chip package and a conductive film. The first chip package includes a first lead-frame with a first inner lead and a first outer lead; a first chip and a first conductive lead electrically connected with the first inner lead; and a first encapsulation body encapsulating the first inner lead, the first chip and the first conductive lead, wherein at least one portion of the first conductive lead is exposed to a surface of the first encapsulation body. The second chip package includes a second lead-frame with a second inner lead and a second outer lead; a second chip electrically connected with the second inner lead; and a second encapsulation body encapsulating the second inner lead and the second chip. The conductive film is arranged between the first chip package and the second chip package to adhere the first chip package with the second chip package and electrically connect the first conductive lead with the second chip package.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a cross-sectional diagram which shown a package on package structure according to one preferred embodiment of the present invention;

FIG. 2 is a cross-sectional diagram which shown a package on package structure according to another preferred embodiment of the present invention; and

FIG. 3 is a cross-sectional diagram which shown a package on package structure according to another preferred embodiment of the present invention.

### DESCRIPTION OF THE PREFERRED EMBODIMENT

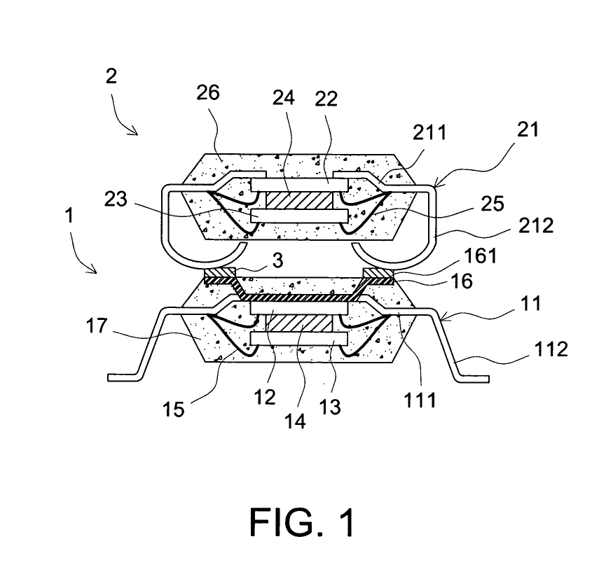

In one preferred embodiment of the present invention, two lead-frame chip packages, which have been tested respectively, are stacked with each other. Please refer to FIG. 1, a package on package structure includes a first chip package 1, a second chip package 2 and a conductive film 3.

The first chip package 1 includes a first lead-frame 11, a first chip 12, a first conductive lead 16 and a first encapsulation body 17. The first lead-frame 11 has a first inner lead 111 and a first outer lead 112. The first chip 12 is electrically connected to the first inner lead 111 by a proper method. In one embodiment, the first chip 12 is electrically connected with the first inner lead 111 by using the wires 15, so that the first chip 12 can be electrically connected to an exterior (not shown) by the first outer lead 112.

The first conductive lead 16 is electrically connected with the first inner lead 111, and the first encapsulation body 17 encapsulates the first inner lead 111, the first chip 12 and the first conductive lead 16. In addition, at least one portion of the first conductive lead 16 is exposed to the surface of the first encapsulation body 17 to be as a first conductive portion 161. Preferably, the first chip package 1 may be a Thin Small Outline Package (TSOP) or a Small Outline J-Lead (SOJ). In the embodiment shown in FIG. 1, the first chip package 1 is the Thin Small Outline Package.

As shown in FIG. 1, the first chip package 1 may also include a plurality of chips, such as the two first chips 12, 13 stacked with each other. Preferably, a spacing element 14 can partition into the two first chips 12, 13 to prevent the wires 15 from contacting the bottom of the stacked chip. Notably, those of ordinary skill in the art may utilize the prior arts to stack and package the chips with the same or different function. As a result, the relative stacking and packaging techniques are not described hereafter.

Please refer to FIG. 1 again, the second chip package 2 includes a second lead-frame 21, a second chip 22 and a second encapsulation body 26. The second lead-frame 21 has a second inner lead 211 and a second outer lead 212. The second chip 22 is electrically connected with the second inner lead 211 by using the wires 25. The second encapsulation body 26 encapsulates the second inner lead 211 and the second chip 22 to form the second chip package 2.

In one embodiment, the second chip package 2 is the Small Outline J-Lead. Similar to the first chip package 1, the second chip package 2 may include a plurality of chips. In one embodiment, a spacing element 24 is arranged between the two second chips 22, 23 to partition into the two second chips 22, 23 with a proper distance.

Accordingly, the conductive film 3 is arranged between the first chip package 1 and the second chip package 2. Therefore, the conductive film 3 may adhere the first chip package 1 to the second chip package 2, and electrically connect the first conductive portion 161, which is exposed from the first conductive lead 16, with the second chip package 2. Illustratively, the conductive film 3 is an anisotropic conductive film (ACF). In one embodiment shown in FIG. 1, the second chip package 2 is electrically connected with the first chip package 1 by the second outer lead 212.

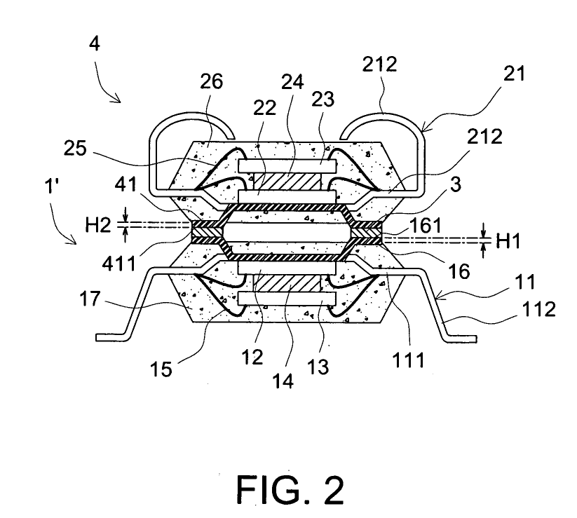

Please refer to FIG. 2 that is another package on package structure of one preferred embodiment according to present invention. The first chip package 1′ is similar to the first chip package 1 (shown in FIG. 1), and their differentiation is that the first conductive portion 161 of the first conductive lead 16 protrudes to one surface of the first encapsulation body 17 with a height H1.

The second chip package 4 is similar to the second chip package 2 (shown in FIG. 1), and their differentiation is that the second chip package 4 further includes a second conductive lead 41. At least one portion of the second conductive lead 41 is exposed to the second encapsulation body 26 to form a second conductive portion 411. Preferably, the second conductive portion 411 protrudes to one surface of the second encapsulation body 26 with a height H2.

According to the FIG. 2, the second chip package 4 is stacked and adhered to the first chip package 1′ by using the conductive film 3, and is electrically connected with the first conductive portion 161 of the first chip package 1′ by using the second conductive portion 411 of the second conductive lead 41.

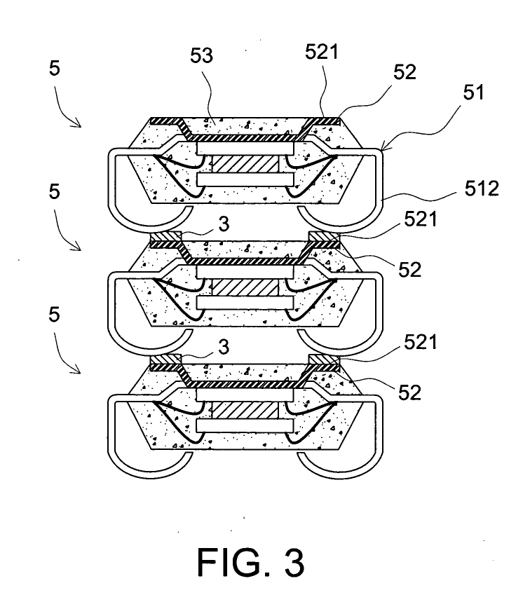

Please refer to FIG. 3 which illustrates another package on package structure of one preferred embodiment according to present invention. A chip package 5 is similar to the second chip package 4 (shown in FIG. 2), and their differentiation is that a conductive portion 521 of a conductive lead 52 of the chip package 5 does not protrude to one surface of an encapsulation body 53. According to the structure of the chip package 5, two chip packages 5 can be stacked with each other and adhered by the conductive film 3. Meanwhile, the upper chip package 5 can be electrically connected with the conductive portion 521 of the conductive lead 52 of the lower chip package 5 by the outer lead 512 of the lead-frame 51.

To sum up, in the package on package structure of the present invention, the conductive lead inside the lead-frame chip package is used to be as the conductive contact between those stacked chip packages. Additionally, the conductive film is applied as the conductive and adhesive material between the stacked chip packages. Thereby, the short-circuit phenomenon between those leads can be improved to elevate the qualified production rate.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. A package on package structure comprising:
a first chip package comprising:
a first lead-frame having a first inner lead and a first outer lead;
a first chip electrically connected with the first inner lead;
a first conductive lead electrically connected with the first inner lead; and
a first encapsulation body encapsulating the first inner lead, the first chip and the first conductive lead, wherein at least one portion of the first conductive lead is exposed to a surface of the first encapsulation body;
a second chip package stacked with the first chip package, and the second chip package comprising:
a second lead-frame having a second inner lead and a second outer lead;
a second chip electrically connected with the second inner lead; and
a second encapsulation body encapsulating the second inner lead and the second chip; and
a conductive film arranged between the first chip package and the second chip package to adhere the first chip package with the second chip package, and electrically connect the first conductive lead with the second chip package.

2. The package on package structure according to claim 1, wherein the conductive film is an anisotropic conductive film.

3. The package on package structure according to claim 1, wherein the second chip package is electrically connected with the first conductive lead by the second outer lead.

4. The package on package structure according to claim 1, wherein the second chip package further comprises:
a second conductive lead electrically connected with the second inner lead, and at least one portion of the second conductive lead is exposed to a surface of the second encapsulation body.

5. The package on package structure according to claim 4, wherein the second conductive lead protrudes to the surface of the second encapsulation body.

6. The package on package structure according to claim 5, wherein the second chip package is electrically connected with the first conductive lead by the second conductive lead.

7. The package on package structure according to claim 1, wherein the first conductive lead protrudes to a surface of the first encapsulation body.

8. The package on package structure according to claim 1, wherein the first chip package is a Thin Small Outline Package (TSOP) or a Small Outline J-Lead (SOJ).

9. The package on package structure according to claim 1, wherein the second chip package is a Small Outline J-Lead (SOJ).
